(19) United States
(12) Patent Application Publication
(10) Pub. No.: US 2012/0264297 A1
(43) Pub. Date: Oct. 18, 2012

(54) METHOD FOR CREATING VIA IN IC MANUFACTURING PROCESS

(75) Inventors: Chung-Fu CHANG, Kaohsiung City (TW); En-Chiuan Liou, Tainan County (TW); I-Ming Tseng, Kaohsiung County (TW); Ssu-I Fu, Kaohsiung County (TW); Wen-Tai Chiang, Tainan County (TW); Cheng-Tzung Tsai, Taipei City (TW)

(73) Assignee: UNITED MICROELECTRONICS CORP., HSINCHU (TW)

(21) Appl. No.: 13/086,881

(22) Filed: Apr. 14, 2011

(51) Int. Cl. H01L 21/28

(52) U.S. Cl. 438/667; 257/E21.158

(57) ABSTRACT

In a method for creating a via in an IC manufacturing process, a substrate is provided and a circuitry structure is formed over the substrate. Then, a dielectric layer is formed over the circuitry structure; a hard mask is formed on and a trench is created through the dielectric layer; a coating layer is formed on the hard mask, filling the trench; an etch opening is defined in the coating layer by performing a pattern transfer process, wherein a width of the etch opening is greater than a width of the trench; and the bottom of the trench exposed from the etch opening is etched off with the hard mask, thereby creating a via for conductors.

### BACKGROUND

1. Technical Field

The present invention relates to a method for creating a via, and more particularly to a method for creating a via in an IC manufacturing process.

2. Description of the Related Art

In an IC manufacturing process, the back end of line (BEoL) involves formation of a multi-layer wiring structure, and via holes are created for passing metal plugs through different layers so as to electrically interconnect metal conductors formed in different layers.

A dual damascene structure is one kind of metal conductor structure which is commonly used in a so-called copper manufacturing process. In the process, precise alignment of the via-patterning mask with the existing trench is critical when defining a via hole in order to assure of sufficient via area for accomplishing circuit quality.

### BRIEF SUMMARY

The present invention provides a method for creating a via in an IC manufacturing process. The method includes steps of: providing a substrate formed thereon a circuitry structure, a dielectric layer and a hard mask; creating a trench through the dielectric layer; forming a coating layer on the hard mask, filling the trench; defining an etch opening in the coating layer by performing a pattern transfer process, wherein a width of the etch opening is greater than a width of the trench; and etching off the bottom of the trench exposed from the etch opening with the hard mask, thereby creating a via for conductors.

According to an embodiment of the present invention, the substrate is a silicon substrate, the dielectric layer is made of a composite material and configured as multiple layers or the dielectric layer is single-layered, the hard mask is made of composite material and configured as multiple layers or the hard mask is single-layered, and the coating layer includes a bottom anti-reflective layer and a photoresist layer.

According to an embodiment of the present invention, the method further comprises: removing the coating layer; forming a metal conductor on the hard mask, filling the via and the trench; and performing a chemical mechanical polishing (CMP) process for removing the hard mask and a portion of the metal conductor protruding from the via.

According to an embodiment of the present invention, the metal conductor is made of copper.

According to an embodiment of the present invention, the etch opening is elliptic in a top view, and has a major axis crossing an extensive direction of the trench.

According to an embodiment of the present invention, an included angle between the major axis of the elliptic photoresis opening and the extensive direction of the trench is 90 degrees.

According to an embodiment of the present invention, more than one trench are formed in the IC manufacturing process, and the etch opening crosses both the trench and an adjacent trench with the width of the etch opening greater than the summed width of adjacent trenches.

According to an embodiment of the present invention, the pattern transfer process is performed with a photo mask.

According to an embodiment of the present invention, a mask opening for performing the pattern transfer process is rectangular in a top view and crosses an extensive direction of the trench.

According to an embodiment of the present invention, an included angle between a long side of the rectangular mask opening and the extensive direction of the trench is 90 degrees.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1A˜1F are schematic cross-sectional views of a partial IC structure during the creation of a via according to an embodiment of the present invention;

FIG. 2A is a schematic top view of a partial IC structure, showing the relationship between the etch opening and the trench created according to the method of FIG. 1;

FIG. 2B is a schematic top view of a partial IC structure, showing an example of the arrangement of the mask opening for creating the elliptic etch opening of FIG. 2A;

FIG. 2C is a schematic top view of a partial IC structure, showing another example of the arrangement of the mask opening for creating etch openings according to an embodiment of the present invention; and

FIG. 2D is a schematic top view of a partial IC structure, showing the relationship between the etch openings and the trenches created according to the embodiment of FIG. 2C.

### DETAILED DESCRIPTION

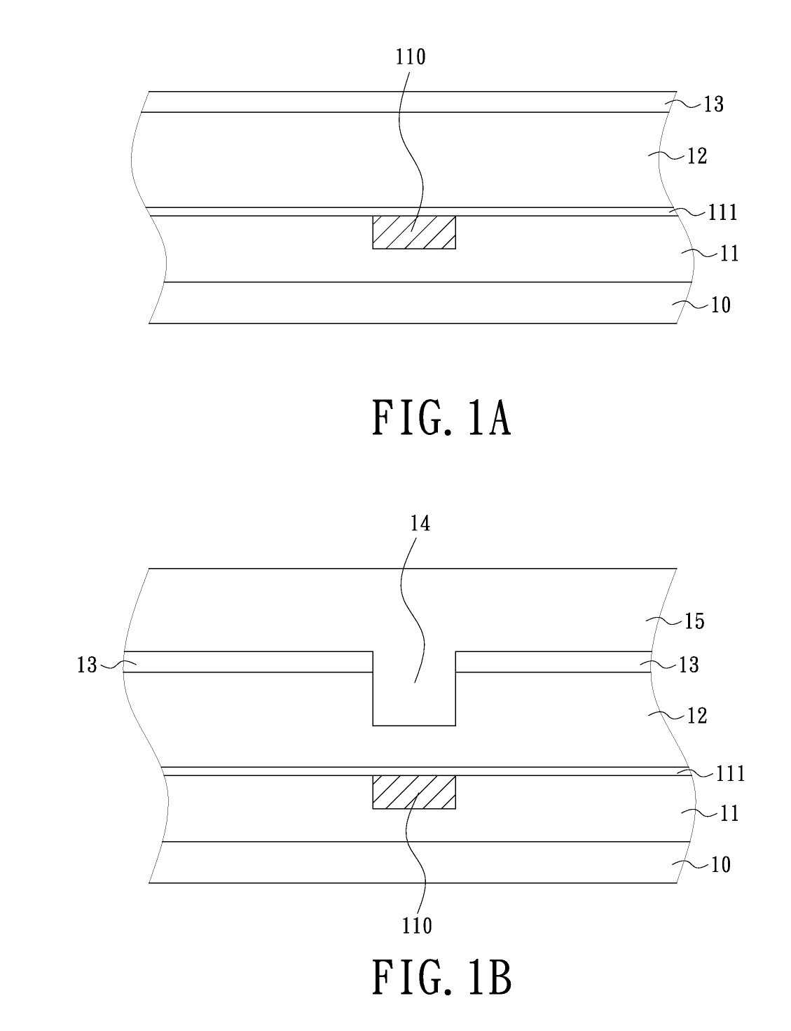

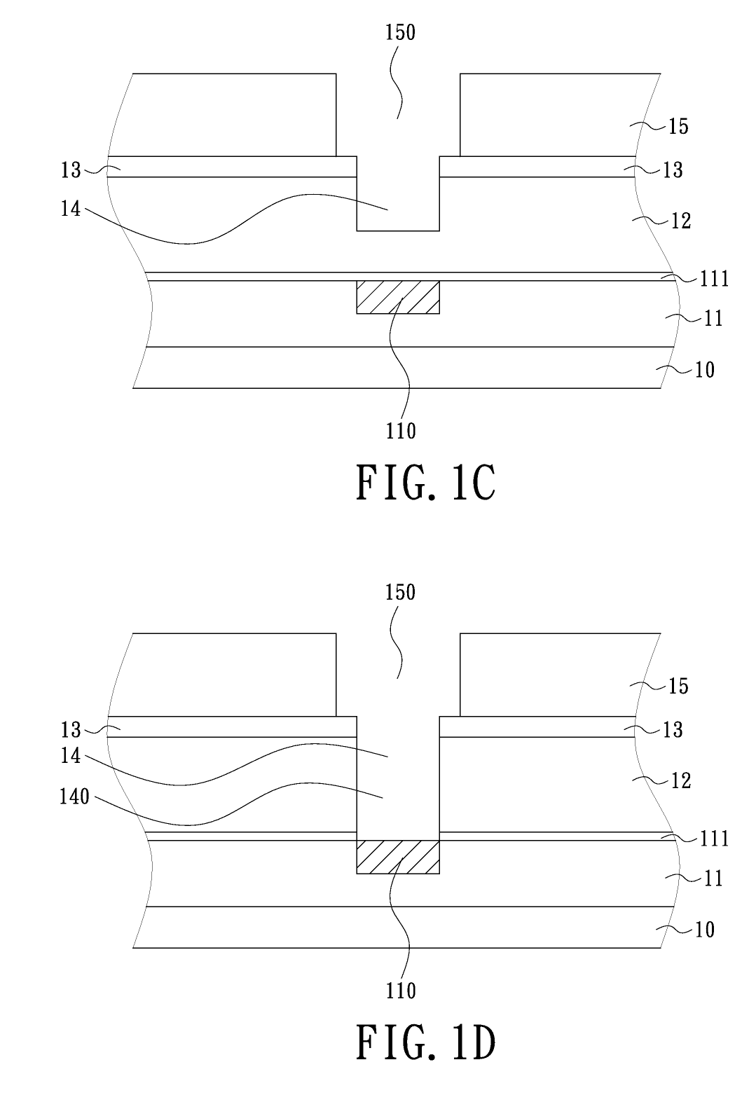

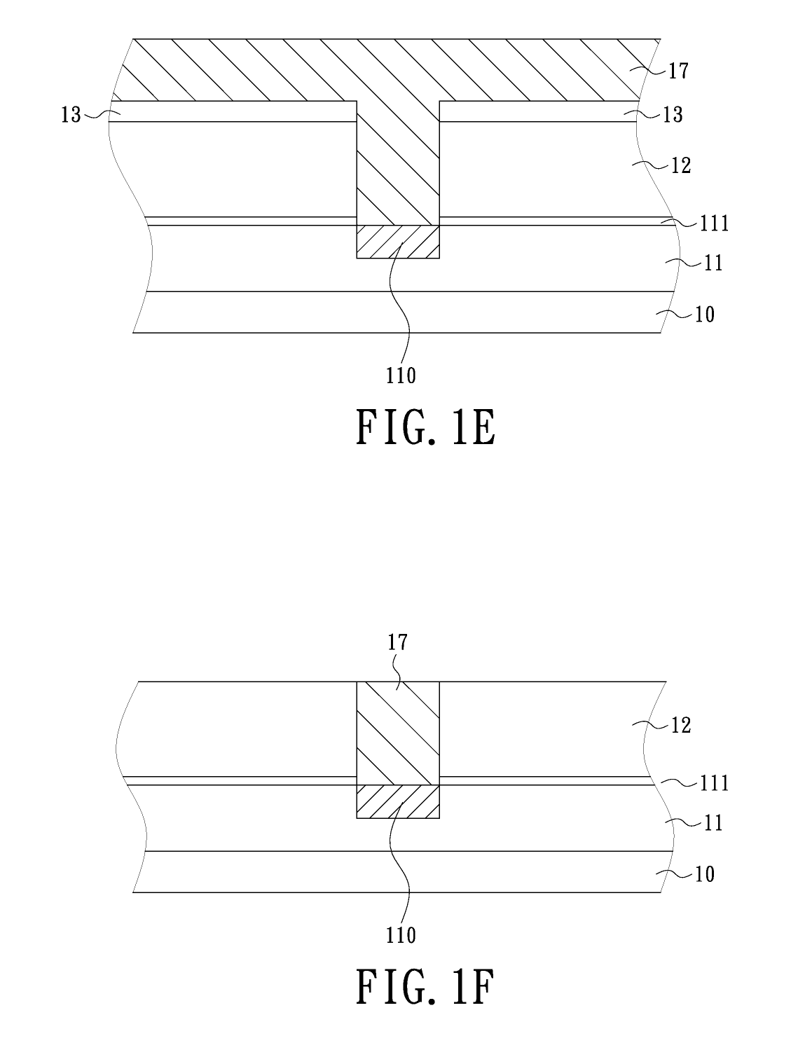

Please refer to FIG. 1A through FIG. 1F, which schematically illustrate the process for creating a via in an IC manufacturing process. In FIG. 1A, a substrate 10 and a circuitry structure 11, a dielectric layer 12 and a hard mask 13 formed on the substrate 10 are schematically shown in a cross-sectional view. The IC manufacturing process in this embodiment is a trench-first Dual Damascene manufacturing process. The substrate 10 is a silicon substrate. The circuitry structure 11 includes a metal conductor 110 and an etch stop layer 111 at the top thereof. The dielectric layer 12 can be multiple-layered or single-layered, and desirably includes a low k material, i.e. of a low dielectric coefficient. For example, the dielectric layer 12 may include on the low k material a sealing layer formed of a relatively dense material and/or a strain-compensating layer formed of a strain-providing material, e.g. TEOS oxide, undoped silicate glass (USG), borophosphosilicate glass (BPSG), SiN, SiC and/or SiON. The hard mask 13 may also be multiple-layered or single-layered, and desirably includes a low k material such as TiN, TaN, Ti and/or a composite layer of an advanced pattern film (APF) and an upper dielectric anti-reflective layer such as SiON or SiO₂, which is available from Applied Materials®. The material can be arbitrarily selected and combined as long as it exhibits high etching selectivity to the dielectric layer 12.

A trench 14 is then defined and created by way of a masking-lithographing-etching process. Subsequently, a coating layer 15 is formed, overlying the surface of the remaining hard mask 13 and filling the trench 14, as shown in FIG. 1B. With another mask (not shown), a pattern transfer process is performed for defining an etch opening 150 in the coating layer 15, as shown in FIG. 1C. In this embodiment, the etch opening 150 is defined with a width greater than the width of the trench 14. With the etch opening 150 and the hard mask 13, etching is performed so as to etch off the bottom of the trench 14, as shown in FIG. 1D. As a result, a via 140 is formed, penetrating through the etch stop layer 111 so as to expose the metal conductor 110. As exemplified with reference to FIG. 1E, after the removal of the remaining photoresist 15, a metal conductor 17, e.g. copper, is formed on the hard mask 13 and fills the via 140 and the trench 14. A chemical mechanical polishing (CMP) process is then performed for removing the hard mask 13 and a portion of the metal conductor 17 protruding from the via 140. The resulting structure is shown in FIG. 1F. Since the width of the etch opening 150 is greater than the width of the trench 14, shift of photo mask is tolerable without sacrificing area of the via 140. Thus the resistance of the conductor can be kept normal. In other words, the electric quality of the IC would not be affected by the shift of the photo mask. The coating layer 15 may include a bottom anti-reflective coating (BARC) and photoresist, and most of the trench 14 may be filled with the bottom anti-reflective coating.

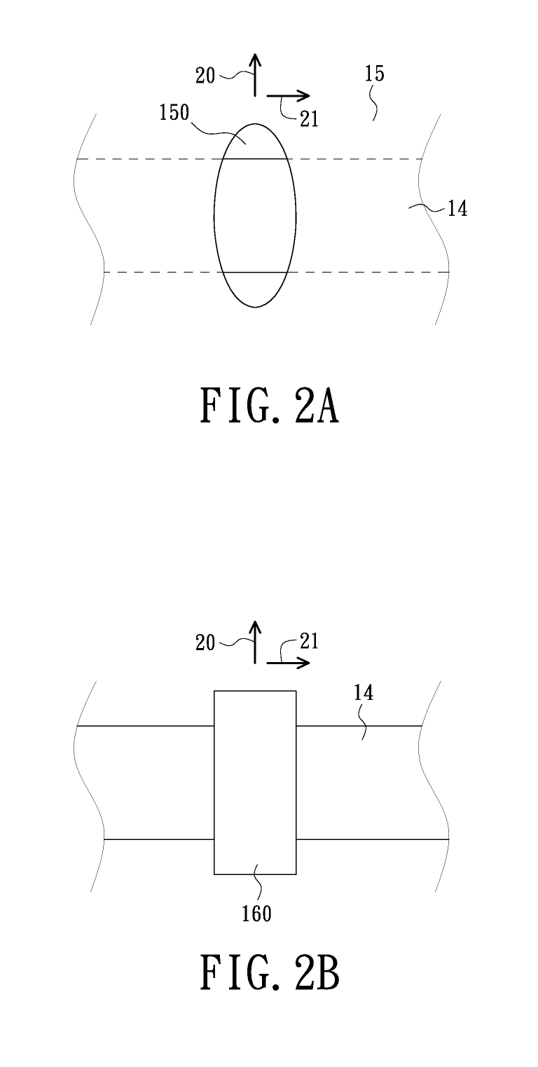

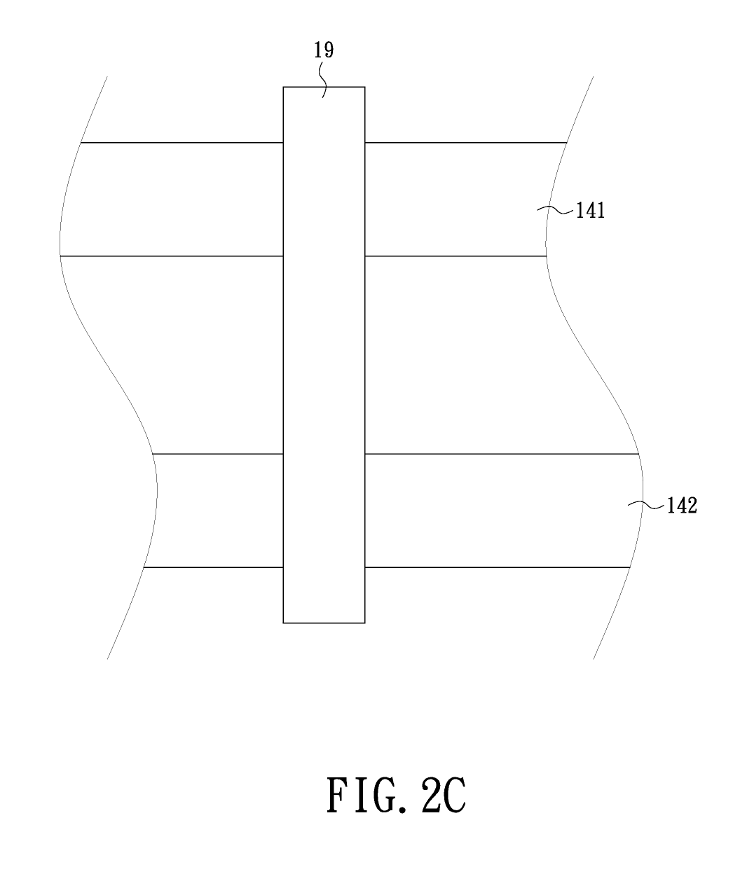

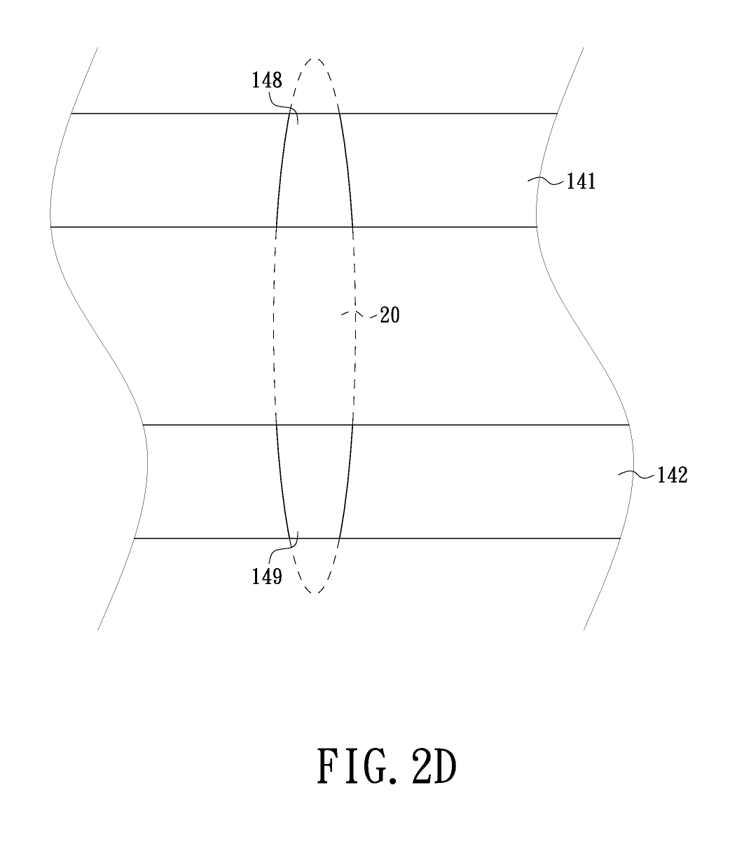

Please refer to FIG. 2A, a relative position of the etch opening 150 to the existing trench 14 is schematically shown. In this embodiment, the etch opening 150 formed in the coating layer 15 is substantially elliptic in the top view. The major axis of the ellipse, as indicated by an arrow 20 in the figure, crosses the extensive direction of the trench 14, as indicated by an arrow 21 in the figure, with an arbitrary angle even though an included angle of 90 degrees is illustrated in the figure. By way of widening etch opening 150 compared to the trench 14, possible shift of the mask in the direction of the arrow 21 to a certain degree in the IC manufacturing process is tolerable since the area of the via can be remained. Furthermore, the via 140 can be aligned with the trench 14 with the existence of the hard mask 13 surrounding the trench 14.

In order to result in the elliptic etch opening 150 as shown in FIG. 2A, a rectangular opening is preferably formed in the mask, as shown in FIG. 2B. The long side of the rectangle, as indicated by an arrow 22 in the figure, crosses the extensive direction of the trench 14, as indicated by an arrow 21 in the figure, with an arbitrary angle even though an included angle of 90 degrees is illustrated in the figure.

FIG. 2C schematically illustrates an example of the arrangement of the mask opening relative to trenches near to each other. In this embodiment, more than one trench are formed in the IC manufacturing process. As shown, the clearance between the trenches 141 and 142 is too small to conform to the lithography resolution. Under this circumstance, adjacent mask openings for creating via holes in adjacent trenches, respectively, can be integrated into a single mask opening 19, and an integrated etch opening 20 is formed, crossing both the trench and an adjacent trench with the width of the etch opening greater than the summed width of adjacent trenches. Accordingly, via 148 and via 149 can be formed in the etch opening 20 and aligned with the trenches 141 and 142 with the existence of the hard mask surrounding the trenches, as shown in FIG. 2D.

The above description is given by way of example, and not limitation. It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. A method for creating a via in an IC manufacturing process, comprising steps of:
providing a substrate formed thereon a circuitry structure, a dielectric layer and a hard mask, wherein the circuitry structure includes a conductor and an etch stop layer directly on the conductor;
creating a trench in the dielectric layer without penetrating the entire dielectric layer;
forming a coating layer on the hard mask, filling the trench;
defining an etch opening in the coating layer by performing a pattern transfer process, wherein a width of the etch opening is greater than a width of the trench; and
creating a via to expose the conductor by etching the dielectric layer and the etch stop layer exposed from the etch opening with the hard mask.

2. The method according to claim 1 wherein the substrate is a silicon substrate, the dielectric layer is made of a composite material and configured as multiple layers or the dielectric layer is single-layered, the hard mask is made of composite material and configured as multiple layers or the hard mask is single-layered, and the coating layer includes a bottom anti-reflective layer and a photoresist layer.

3. The method according to claim 1, further comprising:
removing the coating layer;
forming a metal conductor on the hard mask, filling the via and the trench; and
performing a chemical mechanical polishing (CMP) process for removing the hard mask and a portion of the metal conductor protruding from the via.

4. The method according to claim 3 wherein the metal conductor is made of copper.

5. The method according to claim 1 wherein the etch opening is elliptic in a top view, and has a major axis crossing an extensive direction of the trench.

6. The method according to claim 5 wherein an included angle between the major axis of the elliptic photoresis opening and the extensive direction of the trench is 90 degrees.

7. The method according to claim 1 wherein more than one trench are formed in the IC manufacturing process, and the etch opening crosses both the trench and an adjacent trench with the width of the etch opening greater than the summed width of adjacent trenches.

8. The method according to claim 1 wherein the pattern transfer process is performed with a photo mask.

9. The method according to claim 8 wherein a mask opening for performing the pattern transfer process is rectangular in a top view and crosses an extensive direction of the trench.

10. The method according to claim 9 wherein an included angle between a long side of the rectangular mask opening and the extensive direction of the trench is 90 degrees.
